(19) United States
(12) Patent Application Publication
(10) Pub. No.: US 2022/0415898 A1
(43) Pub. Date: Dec. 29, 2022

(54) SEMICONDUCTOR STRUCTURE, MEMORY STRUCTURE AND FABRICATION METHODS THEREOF

(71) Applicant: CHANGXIN MEMORY TECHNOLOGIES, INC., Hefei (CN)

(72) Inventors: Guangsu SHAO, Hefei (CN); Deyuan XIAO, Hefei (CN)

(21) Appl. No.: 17/899,631

(22) Filed: Aug. 31, 2022

(30) Foreign Application Priority Data
Jun. 16, 2022 (CN) 202210681001.1

(51) Int. Cl. H01L 27/108

(52) U.S. Cl. CPC H01L 27/10814; H01L 27/10852; H01L 27/10873; H01L 27/10885

(57) ABSTRACT

Embodiments relate to a semiconductor structure, a memory structure and fabrication methods thereof. The semiconductor structure includes: a substrate, where a spacer is provided on the substrate, and a bit line structure is provided in the spacer and is at least partially exposed to the spacer; active area structures, where each of the active area structures includes an active pillar and a stress layer, the active pillar is positioned on the bit line structure, and the stress layer covers an exposed surface of the active pillar; each of the active area structure includes a first connection terminal, a second connection terminal, and a channel region positioned between the first connection terminal and the second connection terminal, and the first connection terminal is electrically connected to the bit line structure; and a word line structure covering a periphery of the channel region.

### CROSS-REFERENCE TO RELATED APPLICATION

This application claims priority to Chinese Patent Application No. 202210681001.1, titled “SEMICONDUCTOR STRUCTURE, MEMORY STRUCTURE AND FABRICATION METHODS THEREOF” and filed to the State Patent Intellectual Property Office on Jun. 16, 2022, the entire contents of which are incorporated herein by reference.

### TECHNICAL FIELD

The present disclosure relates to the field of integrated circuit technology, and more particular, to a semiconductor structure, a memory structure and fabrication methods thereof.

### BACKGROUND

With the development of semiconductor technologies, a three-dimensional memory structure has received wide attention from the market due to its higher storage density per unit area than a two-dimensional memory structure, and users have increasingly higher requirements for performance of the three-dimensional memory structure.

A vertical gate-all-around (VGAA) in the three-dimensional memory structure has a greater influence on the performance of the entire three-dimensional memory structure. However, the existing VGAA generally uses a silicon pillar as an active pillar, and a gate word line surrounding a channel region is formed on a periphery of the channel region of the active pillar. However, electron mobility of the active pillar in the existing VGAA is lower, resulting in poorer device performance.

### SUMMARY

The present disclosure provides a semiconductor structure, which includes:

a substrate, wherein a spacer is provided on the substrate, and a bit line structure is provided in the spacer and at least partially exposed to the spacer;

active area structures, wherein each of the active area structures comprises an active pillar and a stress layer, the active pillar is positioned on the bit line structure, and the stress layer covers an exposed surface of the active pillar; each of the active area structure comprises a first connection terminal, a second connection terminal, and a channel region positioned between the first connection terminal and the second connection terminal, and the first connection terminal is electrically connected to the bit line structure; and

a word line structure covering a periphery of the channel region.

The present disclosure provides a method for fabricating a memory structure, including:

providing a substrate;

forming a spacer on a surface of the substrate;

forming a bit line structure in the spacer;

forming an active area structure on the bit line structure, wherein the active area structure comprises an active pillar and a stress layer, the active pillar is positioned on the bit line structure, and the stress layer covers an exposed surface of the active pillar; the active area structure comprises a first connection terminal, a second connection terminal, and a channel region positioned between the first connection terminal and the second connection terminal, and the first connection terminal is electrically connected to the bit line structure; and

forming a word line structure on a periphery of the channel region.

### BRIEF DESCRIPTION OF THE DRAWINGS

To describe the technical solutions in the embodiments of the present disclosure or the existing technologies more clearly, the accompanying drawings required for describing the embodiments or the existing technologies will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a flowchart of a method for fabricating a semiconductor structure provided in an embodiment;

FIG. 2 is a schematic three-dimensional structural diagram of a structure obtained in Step S11 in the method for fabricating a semiconductor structure provided in an embodiment;

FIG. 3 is a schematic three-dimensional structural diagram of a structure obtained in Step S12 in the method for fabricating a semiconductor structure provided in an embodiment;

FIG. 4 is a flowchart of forming a bit line structure in a substrate in Step S13 of the method for fabricating a semiconductor structure provided in an embodiment;

FIG. 5 is a schematic three-dimensional structural diagram of a structure obtained in Step S131 in the method for fabricating a semiconductor structure provided in an embodiment;

FIG. 6 is a schematic three-dimensional structural diagram of a structure obtained in Step S132 in the method for fabricating a semiconductor structure provided in an embodiment;

FIG. 7 is a flowchart of forming an active area structure on the bit line structure in Step S14 in the method for fabricating a semiconductor structure provided in an embodiment;

FIG. 8 is a schematic three-dimensional structural diagram of a structure obtained in Step S141 in the method for fabricating a semiconductor structure provided in an embodiment;

FIG. 9 is a schematic three-dimensional structural diagram of a structure obtained in Step S142 in the method for fabricating a semiconductor structure provided in an embodiment;

FIG. 10 is a schematic three-dimensional structural diagram of a structure obtained in Step S143 in the method for fabricating a semiconductor structure provided in an embodiment;

FIG. 11 is a schematic three-dimensional structural diagram of a structure obtained in Step S144 in the method for fabricating a semiconductor structure provided in an embodiment;

FIG. 12 is a schematic three-dimensional structural diagram of a structure obtained in Step S145 in the method for fabricating a semiconductor structure provided in an embodiment;

FIG. 13 is a schematic three-dimensional structural diagram of a structure obtained by forming a gate oxide layer on an exposed surface of a stress layer in the method for fabricating a semiconductor structure provided in an embodiment;

FIG. 14 is a schematic three-dimensional structural diagram of a structure obtained in Step S15 in the method for fabricating a semiconductor structure provided in an embodiment;

FIG. 15 is a flowchart of forming a word line structure on a periphery of a channel region and forming a connection terminal dielectric layer on a periphery of a first connection terminal and a periphery of the second connection terminal in the method for fabricating a semiconductor structure provided in an embodiment;

FIG. 16 is a schematic three-dimensional structural diagram of a structure obtained in Step S161 in the method for fabricating a semiconductor structure provided in an embodiment;

FIG. 17 is a schematic three-dimensional structural diagram of a structure obtained in Step S162 in the method for fabricating a semiconductor structure provided in an embodiment;

FIG. 18 is a schematic three-dimensional structural diagram of a structure obtained in Step S163 in the method for fabricating a semiconductor structure provided in an embodiment;

FIG. 19 is a schematic three-dimensional structural diagram of a structure obtained in Step S164 in the method for fabricating a semiconductor structure provided in an embodiment;

FIG. 20 is a schematic three-dimensional structural diagram of a structure obtained by forming a filling dielectric layer in isolation trenches, where the filling dielectric layer fills up the isolation trenches, in the method for fabricating a semiconductor structure provided in an embodiment;

FIG. 21 is a schematic three-dimensional structural diagram of a semiconductor structure provided in an embodiment;

FIG. 22 is a schematic three-dimensional structural diagram of a semiconductor structure provided in another embodiment;

FIG. 23 is a flowchart of a method for fabricating a memory structure provided in an embodiment;

FIG. 24 is a schematic three-dimensional structural diagram of a structure obtained in Step S232 in the method for fabricating a memory structure provided in an embodiment;

FIG. 25 is a schematic three-dimensional structural diagram of a structure obtained in Step S233 in the method for fabricating a memory structure provided in an embodiment; and

FIG. 26 is a schematic three-dimensional structural diagram of a memory structure provided in an embodiment.

### DETAILED DESCRIPTION

For ease of understanding the present disclosure, the present disclosure will be described more fully hereinafter with reference to the accompanying drawings. Some embodiments of the present disclosure are provided in the accompanying drawings. The present disclosure may, however, be embodied in many different forms and should not be limited to the embodiments set forth herein. Rather, these embodiments are provided such that the present disclosure will be more thorough and complete.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure.

It should be understood that when an element or layer is referred to as being “on”, “adjacent to”, “connected to” or “coupled to” other elements or layers, it may be directly on, adjacent to, connected or coupled to the other elements or layers, or intervening elements or layers may be present. In contrast, when an element is referred to as being “directly on”, “directly adjacent to”, “directly connected to” or “directly coupled to” other elements or layers, there are no intervening elements or layers present. It should be understood that although the terms first, second, third, etc. may be employed to describe various elements, components, regions, layers, doping types and/or sections, these elements, components, regions, layers, doping types and/or sections should not be limited by these terms. These terms are only employed to distinguish one element, component, region, layer, doping type, or section from another element, component, region, layer, doping type, or section. Thus, without departing from the teachings of the present disclosure, a first element, component, region, layer, doping type or portion discussed below may be represented as a second element, component, region, layer or portion. For example, a first doping type may be a second doping type, and similarly, the second doping type may be the first doping type. Furthermore, the first doping type and the second doping type may be different doping types. For example, the first doping type may be a P type and the second doping type may be an N type, or the first doping type may be the N type and the second doping type may be the P type.

Spatially relative terms such as “below”, “under”, “lower”, “beneath”, “above”, “upper” and the like may be used herein to describe relationships between one element or feature as shown in the figures and another element(s) or feature(s). It should be understood that the spatially relative terms may be intended to encompass different orientations of a device in use or operation in addition to the orientation depicted in the figures. For example, if the device in the figures is turned over, elements or features described as “under”, “beneath” or “below” other elements would then be oriented “above” the other elements or features. Thus, the example term “under”, “below” or “beneath” may encompass both an orientation of above and below. In addition, the device may also be otherwise oriented (for example, rotated 90 degrees or at other orientations) and the spatially relative descriptors used herein should be interpreted accordingly.

As used herein, the singular forms of “a”, “one” and “said/the” are also intended to include plural forms, unless the context clearly indicates otherwise. It should also be understood that the terms “comprising” and/or “including”, when used in this specification, may determine the presence of the described features, integers, steps, operations, elements and/or components, but do not preclude the presence or addition of one or more other features, integers, steps, operations, elements, components, and/or groups thereof. Meanwhile, as used herein, the term “and/or” includes any and all combinations of related listed items.

Embodiments of the present disclosure are described herein with reference to cross-sectional illustrations serving as schematic illustrations of idealized embodiments (and intermediate structures) of the present disclosure. As such, variations from the shapes of the illustrations as a result, for example, of manufacturing techniques and/or tolerances, may be expected. Thus, the embodiments of the present disclosure should not be construed as being limited to particular shapes of regions illustrated herein but may include deviations in shapes that result, for example, from the manufacturing techniques. For example, an injection region shown as a rectangle typically has circular or curved features and/or injection concentration gradients at its edges rather than a binary change from the injection region to a non-injection region. Likewise, a buried region formed by means of injection may result in some injections in a region between the buried region and a surface through which the injection proceeds. Thus, regions illustrated in the figures are schematic in nature and their shapes neither illustrate an actual shape of a region of the device nor limit the scope of the present disclosure.

With the development of semiconductor technologies, a three-dimensional memory structure has received wide attention from the market due to its higher storage density per unit area than a two-dimensional memory structure, and users have increasingly higher requirements for performance of the three-dimensional memory structure. However, in the existing three-dimensional memory structure, due to a design problem of the structure itself or negative effects caused by the fabrication processes, more electrons are accumulated in a bit line structure of the existing three-dimensional memory structure, or poor contact between a drain and the bit line results in lower electron mobility, leading to a device failure.

On this basis, it is necessary to provide a semiconductor structure, a memory structure and fabrication methods thereof, to solve the problems of higher electron accumulation in the bit line structure and lower electron mobility caused by poor contact between the drain and the bit line in the prior art.

To achieve the above objective, the present disclosure provides a method for fabricating a semiconductor structure. As shown in FIG. 1, the method for fabricating a semiconductor structure includes following steps:
S11: providing a substrate;
S12: forming a spacer on a surface of the substrate;
S13: forming a bit line structure in the spacer;
S14: forming an active area structure on the bit line structure, where the active area structure includes an active pillar and a stress layer, the active pillar is positioned on the bit line structure, and the stress layer covers an exposed surface of the active pillar; the active area structure includes a first connection terminal, a second connection terminal, and a channel region positioned between the first connection terminal and the second connection terminal, and the first connection terminal is electrically connected to the bit line structure; and
S15: forming a word line structure on a periphery of the channel region.

In the above example, in the method for fabricating a semiconductor structure of the present disclosure, a stress layer 32 covering an active pillar 31 is formed on a periphery of the active pillar 31 to introduce stress, which can greatly increase the electron mobility of the active pillar 31, such that the performance of the semiconductor structure is improved.

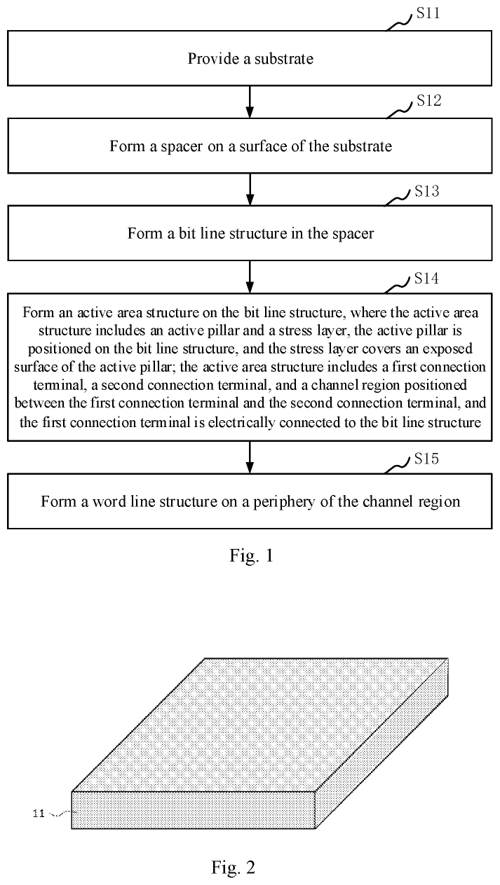

In Step S11, referring to Step S11 in FIG. 1 and FIG. 2, a substrate 11 is provided.

In one embodiment, the substrate 11 may include, but is not limited to, at least one of a silicon substrate, a gallium arsenide substrate, a gallium nitride substrate, and a silicon carbide substrate. In some embodiments, the substrate 11 may be any one of the silicon substrate, the gallium arsenide substrate, the gallium nitride substrate and the silicon carbide substrate, or a composite substrate formed by combining two or more of these substrates.

In Step S12, referring to Step S12 in FIG. 1 and FIG. 3, a spacer 12 is formed on the surface of the substrate 11.

In one embodiment, the spacer 12 may include, but is not limited to, at least one of a silicon oxycarbonitride layer, a silicon oxycarbide layer, a silicon oxide layer, a silicon nitride layer and a silicon carbide layer. In some embodiments, the spacer 12 may be any one of the silicon oxycarbonitride layer, the silicon oxycarbide layer, the silicon oxide layer, the silicon nitride layer and the silicon carbide layer, or a composite layer formed by combining two or more of these layers.

In Step S13, referring to Step S13 in FIG. 1 and FIG. 4 to FIG. 6, a bit line structure 2 is formed in the spacer 12.

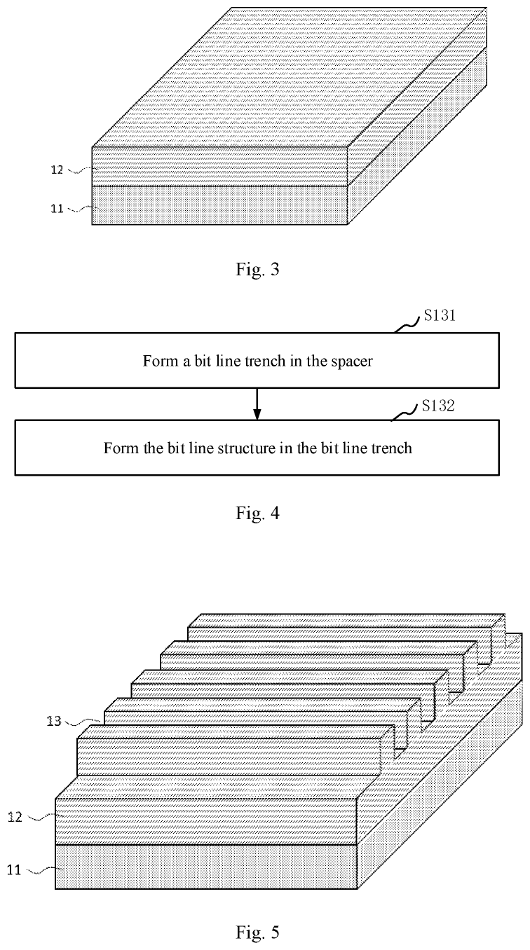

In one example, as shown in FIG. 4, Step S13 of forming a bit line structure 2 in the spacer 12 may include following steps:

S131: forming a bit line trench 13 in the spacer 12, as shown in FIG. 5. In some embodiments, the bit line trench 13 may be formed in the spacer 12 by means of etching.

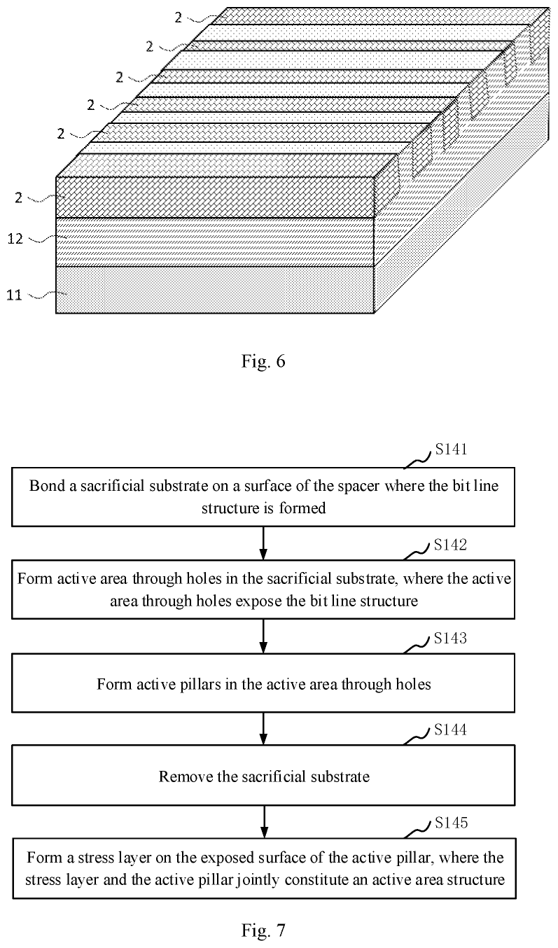

S132: forming the bit line structure 2 in the bit line trench 13, as shown in FIG. 6.

It should be noted that, before forming a bit line trench 13 in the spacer 12, the method further includes a step of performing chemical mechanical polishing on the spacer 12, such that surface flatness of the spacer 12 can meet requirements, avoiding an uneven surface of the spacer 12 from having a negative effect on the semiconductor structure.

In one embodiment, the bit line structure 2 may be a metal structure; and the word line structure 4 may be either a metal structure or a polysilicon structure.

In Step S14, referring to Step S14 in FIG. 1 and FIG. 7 to FIG. 12, an active area structure is formed on the bit line structure 2, and the active area structure includes an active pillar 31 and a stress layer 32, where the active pillar 31 is positioned on the bit line structure 2, and the stress layer 32 covers an exposed surface of the active pillar 31. The active area structure includes a first connection terminal 33, a second connection terminal 34, and a channel region (not shown in the figure) positioned between the first connection terminal 33 and the second connection terminal 34, where the first connection terminal 33 is electrically connected to the bit line structure 2.

In one embodiment, as shown in FIG. 7, the Step S14 of forming an active area structure on the bit line structure 2 may include following steps:

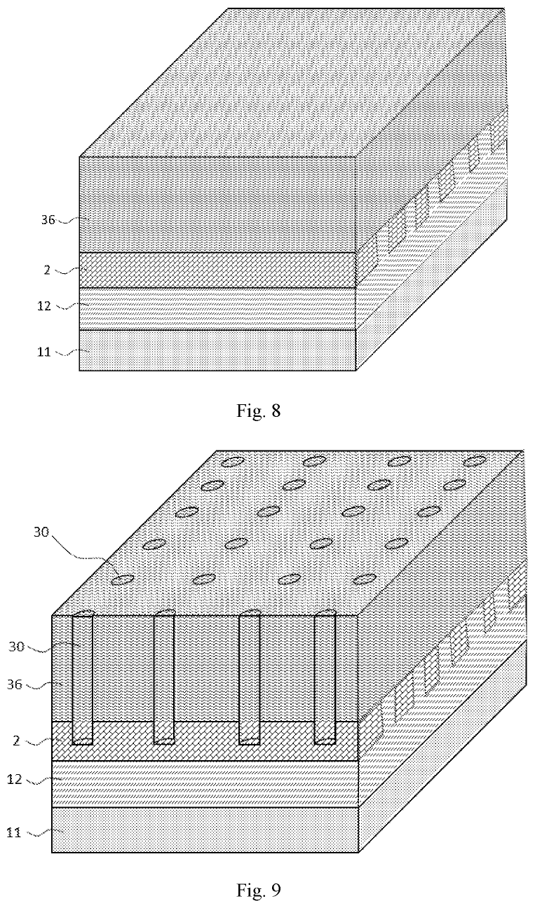

S141: bonding a sacrificial substrate 36 on a surface of the spacer 12 where the bit line structure 2 is formed, as shown in FIG. 8;

S142: forming active area through holes 30 in the sacrificial substrate 36, where the active area through holes 30 expose the bit line structure 2, as shown in FIG. 9;

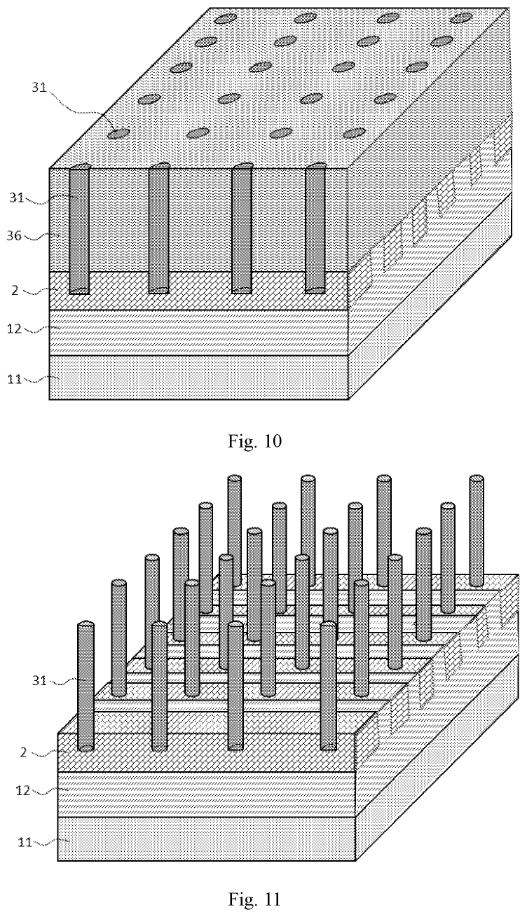

S143: forming active pillars 31 in the active area through holes 30, as shown in FIG. 10;

S144: removing the sacrificial substrate 36, as shown in FIG. 11; and

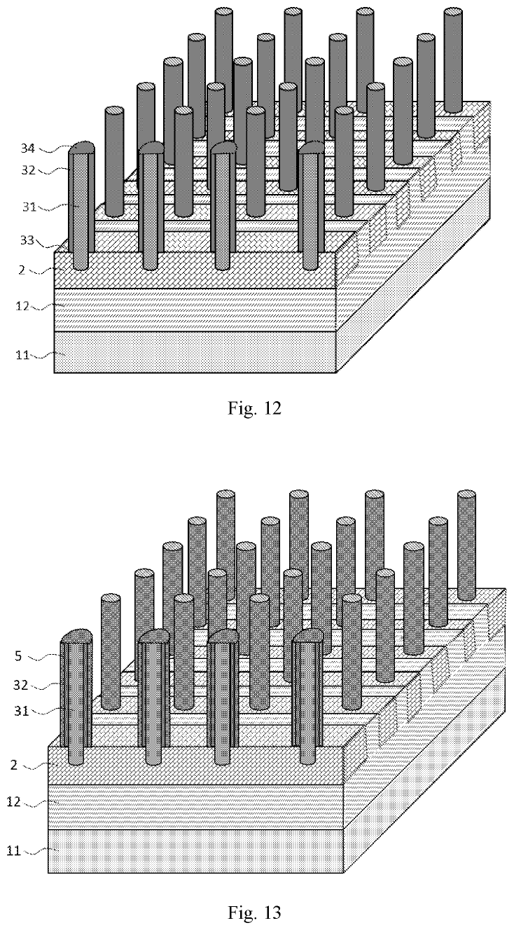

S145: forming a stress layer 32 on the exposed surface of the active pillar 31, where the stress layer 32 and the active pillar 31 jointly constitute an active area structure, as shown in FIG. 12.

In one example, the sacrificial substrate 36 may be a silicon sacrificial substrate or a dielectric layer sacrificial substrate; the sacrificial substrate 36 may be formed, by means of epitaxial growth or deposition, on the surface of the spacer 12 where the bit line structure 2 is formed.

In one embodiment, still referring to FIG. 9 and FIG. 10, the active area through hole 30 may penetrate through the sacrificial substrate 36 along a thickness direction and extend into the bit line structure 2. The active pillar 31 may be embedded in the bit line structure 2, to achieve better contact between the active pillar 31 and the bit line structure 2, thereby reducing a contact resistance and improving an electron transmission rate.

In one embodiment, the active pillar 31 may be formed in the active area through hole 30 by growing the active pillar 31 in the through hole by means of epitaxial growth. A germanium-silicon pillar may be formed in the active area through hole 30 to serve as the active pillar 31. The use of the germanium-silicon pillar can alleviate the adverse effect caused by silicon bonding required when silicon is used as the active pillar 31, and the germanium-silicon pillar is doped silicon germanide. A silicon layer may be formed on the exposed surface of the active pillar 31 to serve as the stress layer 32. Using the silicon layer as the stress layer 32 can help to achieve better contact between the active area structure and the bit line structure 2, to increase the electron mobility, and facilitate electronic transfer between the active area structure and the bit line structure 2.

In one embodiment, still referring to FIG. 9 to FIG. 12, a plurality of active area through holes 30 may be formed in the sacrificial substrate 36 simultaneously, and the active area through holes 30 may be arranged in multiple rows and multiple columns. The active pillar 31 is formed in each of the active area through holes 30. After the stress layer 32 is formed, a plurality of active area structures are obtained, and the active area structures are arranged in multiple rows and multiple columns. A plurality of bit line structures 2 are formed in the spacer 12, and the plurality of bit line structures 2 are arranged in parallel at intervals, and extend along a row direction of the active area structures. Such an orderly arranged structure does not cause disorder of electrical connections inside the semiconductor structure, thereby greatly reducing the risk of short circuit and improving device performance.

In one embodiment, after forming the stress layer 32 on the exposed surface of the active pillar 31, the method further includes a step of forming a gate oxide layer 5 on the exposed surface of the stress layer 32, where a structure obtained is shown in FIG. 13.

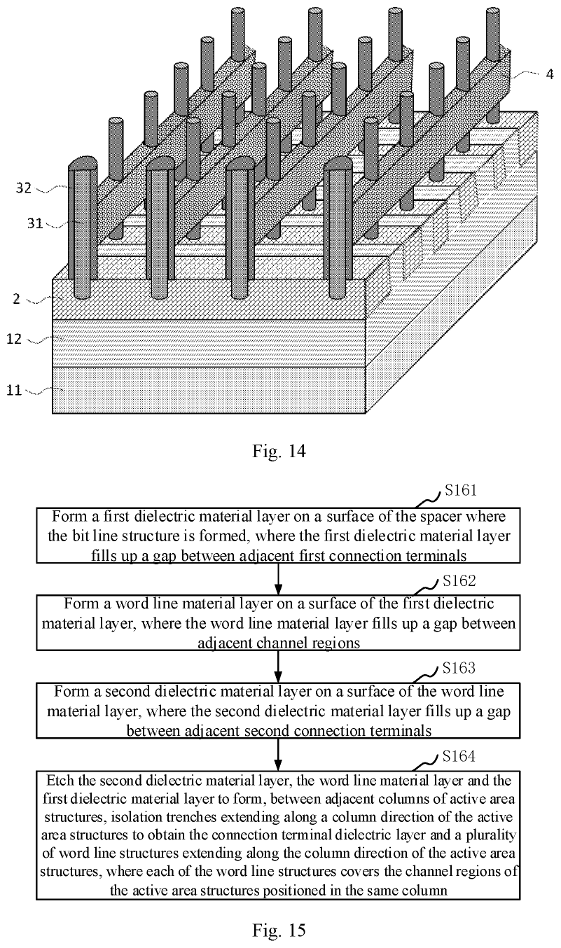

In Step S15, referring to Step S15 in FIG. 1 and FIG. 14, the word line structure 4 is formed on the periphery of the channel region.

In one embodiment, while the word line structure 4 is formed on the periphery of the channel region, a connection terminal dielectric layer is also formed on a periphery of the first connection terminal 33 and a periphery of the second connection terminal 34. As shown in FIG. 15, the forming a word line structure 4 on a periphery of the channel region, and forming a connection terminal dielectric layer on a periphery of the first connection terminal 33 and a periphery of the second connection terminal 34 may include following steps:

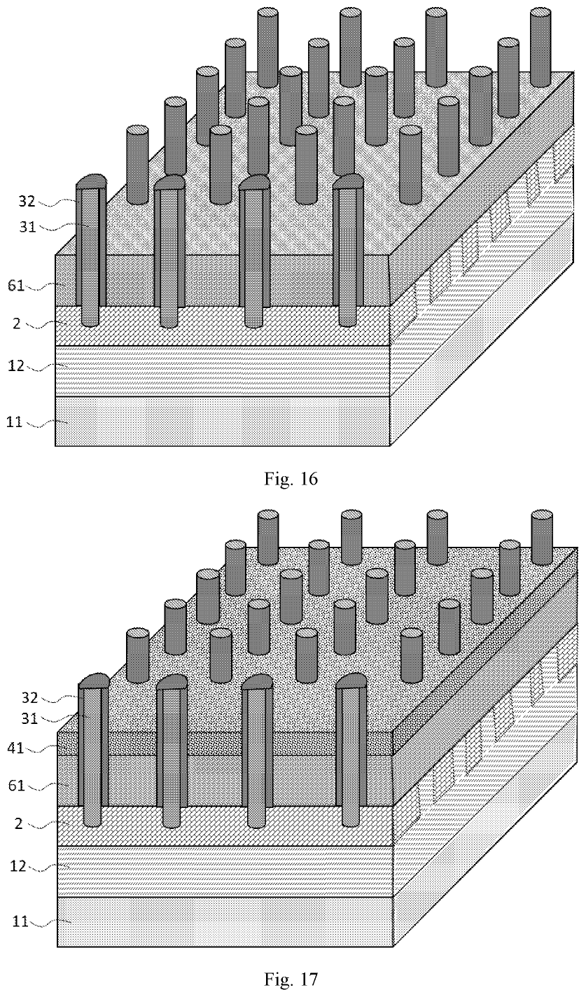

S161: forming a first dielectric material layer 61 on a surface of the spacer 12 where the bit line structure 2 is formed, where the first dielectric material layer 61 fills up a gap between adjacent first connection terminals, as shown in FIG. 16;

S162: forming a word line material layer 41 on a surface of the first dielectric material layer 61, where the word line material layer 41 fills up a gap between adjacent channel regions, as shown in FIG. 17;

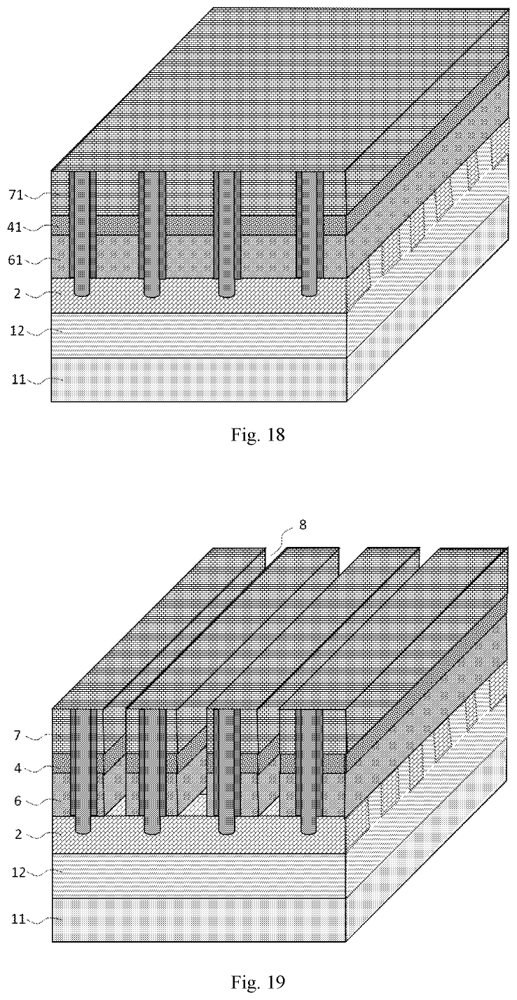

S163: forming a second dielectric material layer 71 on a surface of the word line material layer 41, where the second dielectric material layer 71 fills up a gap between adjacent second connection terminals, as shown in FIG. 18; and

S164: etching the second dielectric material layer 71, the word line material layer 41 and the first dielectric material layer 61 to form, between adjacent columns of active area structures, isolation trenches 8 extending along a column direction of the active area structures to obtain the connection terminal dielectric layer and a plurality of word line structures 4 extending along the column direction of the active area structures, where each of the word line structures 4 covers the channel regions of the active area structures positioned in the same column, as shown in FIG. 19.

In some embodiments, still referring to FIG. 19, the connection terminal dielectric layer may include a connection terminal dielectric layer 6 and a connection terminal dielectric layer 7, where the connection terminal dielectric layer 6 is positioned on the periphery of the first connection terminal, and the connection terminal dielectric layer 7 is positioned on the periphery of the second connection terminal.

In one embodiment, the first dielectric material layer 61 may include, but is not limited to, at least one of a silicon oxycarbonitride layer, a silicon oxycarbide layer, a silicon oxide layer, a silicon nitride layer, and a silicon carbide layer. In some embodiments, the first dielectric material layer 61 may be any one of the silicon oxycarbonitride layer, the silicon oxycarbide layer, the silicon oxide layer, the silicon nitride layer and the silicon carbide layer, or a composite layer formed by combining two or more of these layers. The word line material layer 41 may be a metal material layer. The second dielectric material layer 71 may include, but is not limited to, at least one of a silicon oxycarbonitride layer, a silicon oxycarbide layer, a silicon oxide layer, a silicon nitride layer and a silicon carbide layer. In some embodiments, the second dielectric material layer 71 may be any one of the silicon oxycarbonitride layer, the silicon oxycarbide layer, the silicon oxide layer, the silicon nitride layer and the silicon carbide layer, or a composite layer formed by combining two or more of these layers. The connection terminal dielectric layer may include, but is not limited to, at least one of a silicon oxycarbonitride layer, a silicon oxycarbide layer, a silicon oxide layer, a silicon nitride layer and a silicon carbide layer. In some embodiments, the connection terminal dielectric layer may be any one of the silicon oxycarbonitride layer, the silicon oxycarbide layer, the silicon oxide layer, the silicon nitride layer and the silicon carbide layer, or a composite layer formed by combining two or more of these layers.

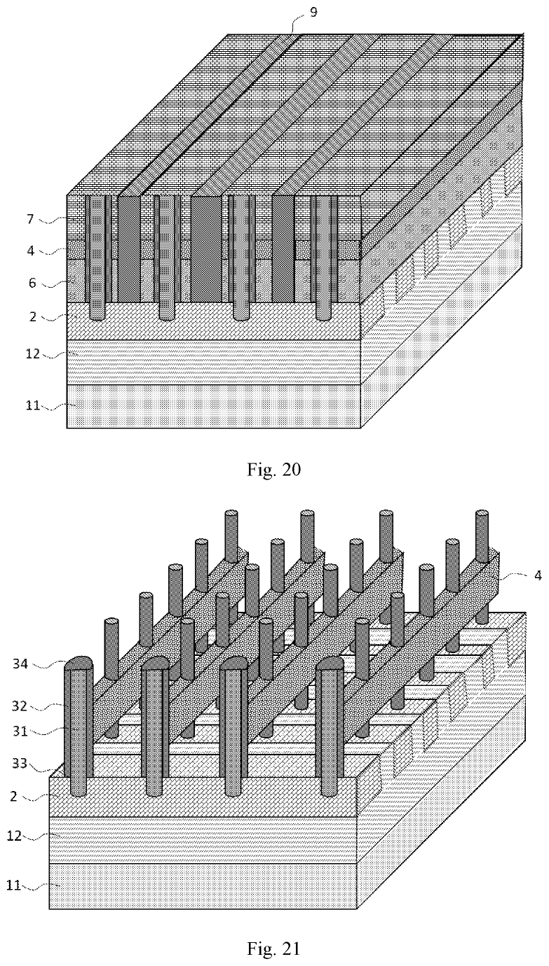

In one embodiment, after forming the isolation trenches 8, the method further includes a step of forming a filling dielectric layer 9 in the isolation trenches 8, where the filling dielectric layer 9 fills up the isolation trenches 8, and a structure obtained is shown in FIG. 20. The filling dielectric layer 9 may include, but is not limited to, at least one of a silicon oxycarbonitride layer, a silicon oxycarbide layer, a silicon oxide layer, a silicon nitride layer and a silicon carbide layer. In some embodiments, the filling dielectric layer 9 may be any one of the silicon oxycarbonitride layer, the silicon oxycarbide layer, the silicon oxide layer, the silicon nitride layer and the silicon carbide layer, or a composite layer formed by combining two or more of these layers.

It is to be understood that although the various steps in the flowcharts involved in various aforementioned embodiments are displayed in sequence as indicated by the arrows, these steps are not necessarily performed in sequence in the order indicated by the arrows. Unless expressly stated herein, the execution of these steps is not strictly restrictive and may be performed in other order. Moreover, at least a part of the steps in the flowcharts involved in various aforementioned embodiments may include a plurality of steps or a plurality of stages, which are not necessarily performed at the same moment, but may be executed at different moments, and the order of execution of these steps or stages is not necessarily performed sequentially, but may be performed alternately or alternately with other steps or at least a part of the steps or stages of other steps.

Based on the same inventive concept, the present disclosure also provides a semiconductor structure. Referring to FIG. 21, the semiconductor structure includes a substrate 11, a spacer 12, an active area structure, and a word line structure 4. The substrate 11 has the spacer 12, the spacer 12 has a bit line structure 2, and the bit line structure 2 is at least partially exposed to the spacer 12. The active area structure includes an active pillar 31 and a stress layer 32, where the active pillar 31 is positioned on the bit line structure 2, and the stress layer 32 covers an exposed surface of the active pillar 31. The active area structure includes a first connection terminal 33, a second connection terminal 34, and a channel region (not shown in the figure) positioned between the first connection terminal 33 and the second connection terminal 34, where the first connection terminal 33 is electrically connected to the bit line structure 2. The word line structure 4 covers the periphery of the channel region.

In the above example, the semiconductor structure of the present disclosure includes a substrate 11, a spacer 12, an active area structure, and a word line structure 4. The spacer 12 has a bit line structure 2, and the active area structure includes an active pillar 31 and a stress layer 32, where the active pillar 31 is positioned on the bit line structure 2, and the stress layer 32 covers an exposed surface of the active pillar 31. The stress layer 32 covering the active pillar 31 is arranged on the periphery of the active pillar 31 to introduce stress, which can greatly increase the electron mobility of the active pillar 31, such that the performance of the semiconductor structure is improved.

In one embodiment, the substrate 11 may include, but is not limited to, at least one of a silicon substrate 11, a gallium arsenide substrate 11, a gallium nitride substrate 11, and a silicon carbide substrate 11. In some embodiments, the substrate 11 may be any one of the silicon substrate 11, the gallium arsenide substrate 11, the gallium nitride substrate 11 and the silicon carbide substrate 11, or a composite substrate 11 formed by combining two or more of the foregoing substrates. The spacer 12 may include, but is not limited to, at least one of a silicon oxycarbonitride layer, a silicon oxycarbide layer, a silicon oxide layer, a silicon nitride layer, and a silicon carbide layer. In some embodiments, the spacer 12 may be any one of the silicon oxycarbonitride layer, the silicon oxycarbide layer, the silicon oxide layer, the silicon nitride layer and the silicon carbide layer, or a composite layer formed by combining two or more of these layers.

In one embodiment, the bit line structure 2 may be a metal structure; and the word line structure 4 may be either a metal structure or a polysilicon structure.

In one embodiment, the surface of the stress layer 32 may be covered by a gate oxide layer 5, as shown in FIG. 13.

In one embodiment, still referring to FIG. 21, the active pillar 31 may be embedded in the bit line structure 2, such that the active area structure and the bit line structure 2 are in sufficient contact, thereby reducing the contact resistance between the active area structure and the bit line structure 2.

In one embodiment, still referring to FIG. 21, the active area structures are arranged in multiple rows and multiple columns; a plurality of bit line structures 2 are formed in the spacer 12, and the plurality of bit line structures 2 are arranged in parallel at intervals, and extend along a row direction of the active area structures. A plurality of word line structures 4 are provided, the plurality of word line structures 4 are arranged in parallel at intervals and extend along a column direction of the active area structures, and each of the word line structures 4 covers the channel regions of the active area structures positioned in the same column. Such an orderly arranged structure does not cause disorder of electrical connections inside the semiconductor structure, thereby greatly reducing the risk of short circuit and improving device performance.

In one embodiment, as shown in FIG. 22, the semiconductor structure further includes an insulating dielectric layer, where the insulating dielectric layer is positioned between adjacent word line structures and fills the gaps between the active area structures. The insulating dielectric layer may include a connection terminal dielectric layer and a filling dielectric layer 9. With reference to FIG. 21 and FIG. 22, the connection terminal dielectric layer covers the periphery of the first connection terminal and the periphery of the second connection terminal; and the filling dielectric layer 9 is positioned on the periphery of the connection terminal dielectric layer and the periphery of the word line structure 4.

In some embodiments, still referring to FIG. 21 and FIG. 22, the connection terminal dielectric layer may include a connection terminal dielectric layer 6 and a connection terminal dielectric layer 7, where the connection terminal dielectric layer 6 is positioned on the periphery of the first connection terminal 33, and the connection terminal dielectric layer 7 is positioned on the periphery of the second connection terminal 34.

In one embodiment, the connection terminal dielectric layer may include, but is not limited to, at least one of a silicon oxycarbonitride layer, a silicon oxycarbide layer, a silicon oxide layer, a silicon nitride layer, and a silicon carbide layer. In some embodiments, the connection terminal dielectric layer may be any one of the silicon oxycarbonitride layer, the silicon oxycarbide layer, the silicon oxide layer, the silicon nitride layer and the silicon carbide layer, or a composite layer formed by two or more of these layers. The filling dielectric layer 9 may include, but is not limited to, at least one of a silicon oxycarbonitride layer, a silicon oxycarbide layer, a silicon oxide layer, a silicon nitride layer and a silicon carbide layer. In some embodiments, the filling dielectric layer 9 may be any one of the silicon oxycarbonitride layer, the silicon oxycarbide layer, the silicon oxide layer, the silicon nitride layer and the silicon carbide layer, or a composite layer formed by two or more of these layers.

In one embodiment, the active pillar 31 may include a germanium-silicon pillar, and the germanium-silicon pillar can alleviate the adverse effect caused by silicon bonding required when silicon is used as the active pillar 31 in the prior art, and the germanium-silicon pillar is doped silicon germanide. The use of the silicon layer as the stress layer 32 can help to achieve better contact between the active area structure and the bit line structure 2, to increase the electron mobility, and facilitate electron transfer between the active area structure and the bit line structure 2, where the stress layer 32 includes the silicon layer.

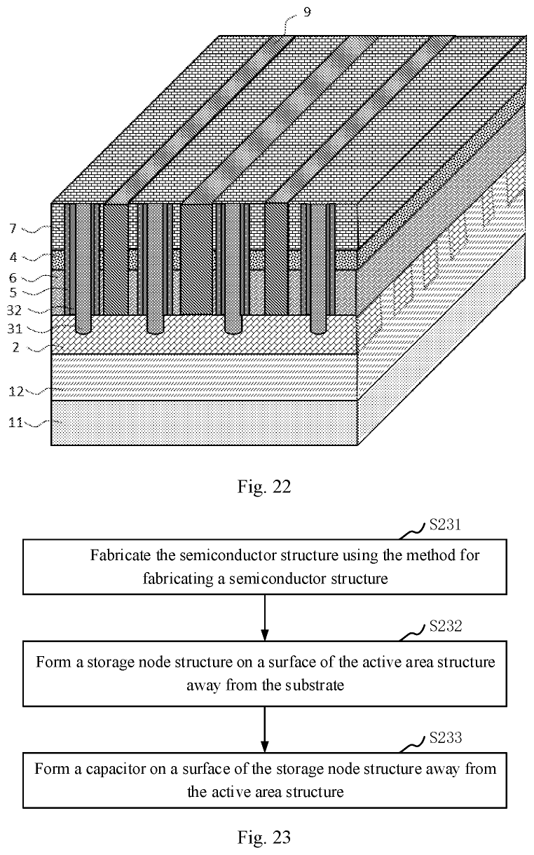

Based on the same inventive concept, the present disclosure also provides a method for fabricating a memory structure. As shown in FIG. 23, the method for fabricating a memory structure includes following steps:

S231: fabricating the semiconductor structure using the method for fabricating a semiconductor structure according to any one of the above solutions;

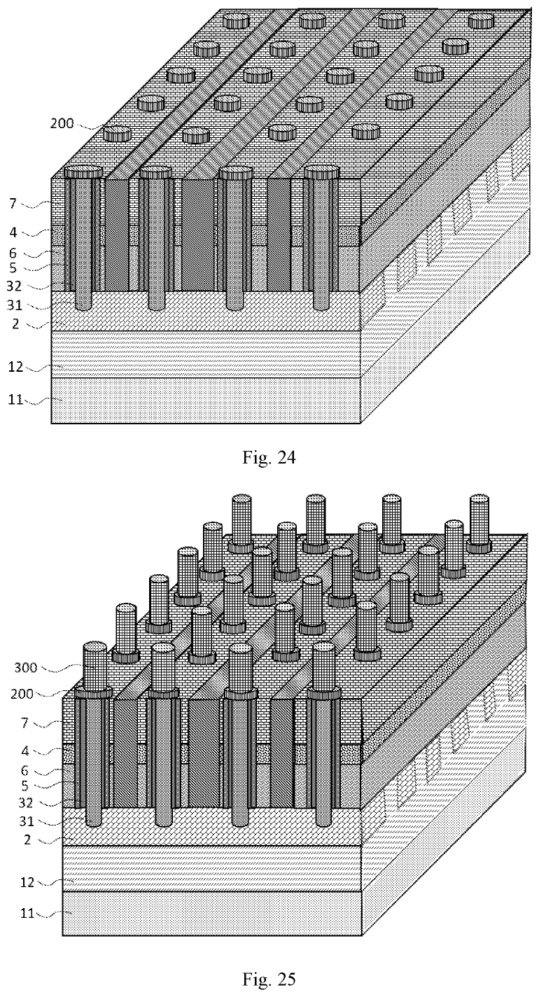

S232: forming a storage node structure 200 on a surface of the active area structure away from the substrate 11, as shown in FIG. 24; and

S233: forming a capacitor 300 on a surface of the storage node structure 200 away from the active area structure, as shown in FIG. 25.

The method for fabricating a memory structure of the present disclosure includes fabricating the semiconductor structure, the storage node structure 200 and the capacitor 300 in any one of the above solutions. Reference may be made to the beneficial effects of the semiconductor structure and the method for fabricating a semiconductor structure provided by the present disclosure for beneficial effects of the method for fabricating a memory structure, and details will not be described herein again.

In one embodiment, referring to FIG. 25, the active area structures are arranged in multiple rows and multiple columns; and a plurality of bit line structures 2 are formed in the spacer 12, and the plurality of bit line structures 2 are arranged in parallel at intervals, and extend along a row direction of the active area structures. A plurality of word line structures 4 are provided, the plurality of word line structures 4 are arranged in parallel at intervals and extend along a column direction of the active area structures, and each of the word line structures 4 covers the channel regions of the active area structures positioned in the same column. A plurality of storage node structures 200 are formed on the surface of the active area structure away from the substrate 11, where the storage node structures 200 are arranged in a one-to-one correspondence with the active area structures. A plurality of capacitors 300 are formed on the surface of the storage node structure 200 away from the active area structure, where the capacitors 300 are arranged in a one-to-one correspondence with the storage node structure 200. Each of the capacitors 300 include a lower electrode, a capacitor dielectric layer positioned on a surface of the lower electrode, and an upper electrode positioned on the capacitor dielectric layer away from the surface of the lower electrode. The lower electrodes of adjacent capacitors 300 are insulated and isolated by the capacitor dielectric layer, and the upper electrodes of all the capacitors 300 may be connected to each other.

It is to be understood that although the various steps in the flowcharts involved in various aforementioned embodiments are displayed in sequence as indicated by the arrows, these steps are not necessarily performed in sequence in the order indicated by the arrows. Unless expressly stated herein, the execution of these steps is not strictly restrictive and may be performed in other order. Moreover, at least a part of the steps in the flowcharts involved in various aforementioned embodiments may include a plurality of steps or a plurality of stages, which are not necessarily performed at the same moment, but may be executed at different moments, and the order of execution of these steps or stages is not necessarily performed sequentially, but may be performed alternately or alternately with other steps or at least a part of the steps or stages of other steps.

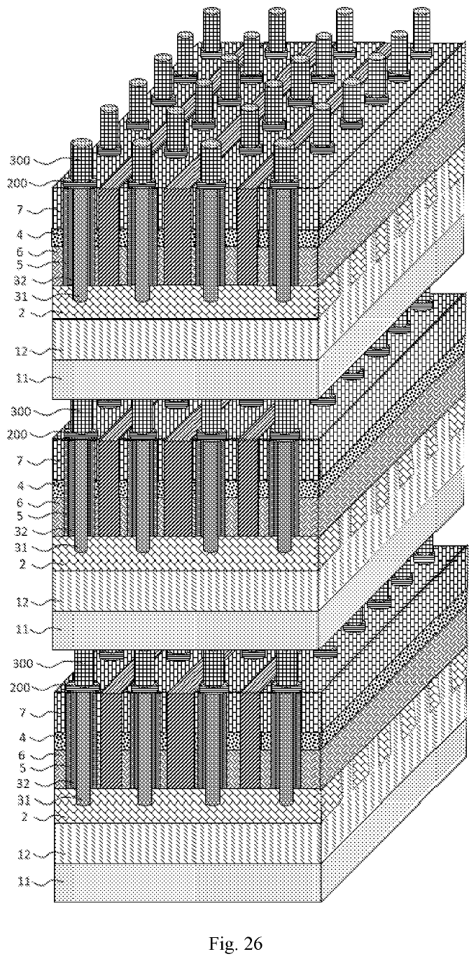

Based on the same inventive concept, the present disclosure also provides a memory structure. As shown in FIG. 26, the memory structure includes: the semiconductor structure, the storage node structure 200 and the capacitor 300 described in any of the above solutions. The storage node structure 200 is positioned on the surface of the active area structure away from the substrate 11; and the capacitor 300 is positioned on a surface of the storage node structure 200 away from the active area structure.

In one embodiment, referring to FIG. 26, the active area structures are arranged in multiple rows and multiple columns; and a plurality of bit line structures 2 are formed in the spacer 12, and the plurality of bit line structures 2 are arranged in parallel at intervals, and extend along a row direction of the active area structures. A plurality of word line structures 4 are provided, the plurality of word line structures 4 are arranged in parallel at intervals and extend along a column direction of the active area structures, and each of the word line structures 4 covers the channel regions of the active area structures positioned in the same column. A plurality of storage node structures 200 are provided, where the storage node structures 200 are arranged in a one-to-one correspondence with the active area structures. A plurality of capacitors 300 are provided, where the capacitors 300 are arranged in a one-to-one correspondence with the storage node structure 200. Each of the capacitors 300 include a lower electrode, a capacitor dielectric layer positioned on a surface of the lower electrode, and an upper electrode positioned on the capacitor dielectric layer away from the surface of the lower electrode. The lower electrodes of adjacent capacitors 300 are insulated and isolated by the capacitor dielectric layer, and the upper electrodes of all the capacitors 300 may be connected to each other.

The memory structure of the present disclosure includes a semiconductor structure, the storage node structures 200 and the capacitors 300 of any one of the above solutions. The beneficial effects of the semiconductor structure are as described above, such as lower contact resistance and higher electron mobility. The storage node structures 200 are arranged in a one-to-one correspondence with the active area structures, and the capacitors 300 are arranged in a one-to-one correspondence with the storage node structures 200. Lower electrodes of the capacitors 300 are insulated and isolated from each other, and upper electrodes of all the capacitors 300 are connected to each other. The semiconductor structure, the storage node structures 200 and the capacitors 300 jointly constitute the memory structure with lower contact resistance and higher electron mobility provided by the present disclosure.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express a plurality of implementations of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be subject to the appended claims.

What is claimed is:

1. A semiconductor structure, comprising:
a substrate, wherein a spacer is provided on the substrate, and a bit line structure is provided in the spacer and is at least partially exposed to the spacer;
active area structures, wherein each of the active area structures comprises an active pillar and a stress layer, the active pillar is positioned on the bit line structure, and the stress layer covers an exposed surface of the active pillar; each of the active area structure comprises a first connection terminal, a second connection terminal, and a channel region positioned between the first connection terminal and the second connection terminal, and the first connection terminal is electrically connected to the bit line structure; and
a word line structure covering a periphery of the channel region.

2. The semiconductor structure according to claim 1, wherein the active pillar is embedded in the bit line structure.

3. The semiconductor structure according to claim 1, wherein the active area structures are arranged in multiple rows and multiple columns, the spacer comprises a plurality of bit line structures, and the plurality of bit line structures are arranged in parallel at intervals and extend along a row direction of the active area structures; a plurality of word line structures are provided, the plurality of word line structures are arranged in parallel at intervals and extend along a column direction of the active area structures, and each of the plurality of word line structures covers the channel regions of the active area structures positioned in the same column.

4. The semiconductor structure according to claim 1, further comprising an insulating dielectric layer, wherein the insulating dielectric layer is positioned between adjacent two of the word line structures and fills up a gap between adjacent two of the active area structures.

5. The semiconductor structure according to claim 4, wherein the insulating dielectric layer comprises:
a connection terminal dielectric layer covering a periphery of the first connection terminal and a periphery of the second connection terminal; and
a filling dielectric layer positioned on a periphery of the connection terminal dielectric layer and a periphery of the word line structure.

6. The semiconductor structure according to claim 1, wherein the active pillar comprises a germanium-silicon pillar, and the stress layer comprises a silicon layer.

7. A method for fabricating a semiconductor structure, comprising:
providing a substrate;
forming a spacer on a surface of the substrate;
forming a bit line structure in the spacer;
forming an active area structure on the bit line structure, wherein the active area structure comprises an active pillar and a stress layer, the active pillar is positioned on the bit line structure, and the stress layer covers an exposed surface of the active pillar; the active area structure comprises a first connection terminal, a second connection terminal, and a channel region positioned between the first connection terminal and the second connection terminal, and the first connection terminal is electrically connected to the bit line structure; and
forming a word line structure on a periphery of the channel region.

8. The method for fabricating a semiconductor structure according to claim 7, wherein the forming a bit line structure in the spacer comprises:
forming a bit line trench in the spacer; and
forming the bit line structure in the bit line trench.

9. The method for fabricating a semiconductor structure according to claim 8, wherein the forming an active area structure on the bit line structure comprises:
bonding a sacrificial substrate on a surface of the spacer where the bit line structure is formed;
forming an active area through hole in the sacrificial substrate, wherein the active area through hole exposes the bit line structure;
forming the active pillar in the active area through hole;
removing the sacrificial substrate; and
forming the stress layer on an exposed surface of the active pillar, wherein the stress layer and the active pillar jointly constitute the active area structure.

10. The method for fabricating a semiconductor structure according to claim 9, wherein the active area through hole penetrates through the sacrificial substrate along a thickness direction and extends into the bit line structure; and the active pillar is embedded into the bit line structure.

11. The method for fabricating a semiconductor structure according to claim 9, wherein a germanium-silicon pillar is formed in the active area through hole to serve as the active pillar, and a silicon layer is formed on the exposed surface of the active pillar to serve as the stress layer.

12. The method for fabricating a semiconductor structure according to claim 9, wherein a plurality of active area through holes are formed in the sacrificial substrate, and the plurality of active area through holes are arranged in multiple rows and multiple columns; the active pillar is formed in each of the plurality of active area through holes; after the stress layer is formed, a plurality of active area structures are obtained, and the plurality of active area structures are arranged in multiple rows and multiple columns; a plurality of bit line structures are formed in the spacer, and the plurality of bit line structures are arranged in parallel at intervals and extend along a row direction of the plurality of active area structures.

13. The method for fabricating a semiconductor structure according to claim 12, further comprising forming a connection terminal dielectric layer on a periphery of the first connection terminal and a periphery of the second connection terminal when forming a word line structure on a periphery of the channel region, wherein the forming a word line structure on a periphery of the channel region, and forming a connection terminal dielectric layer on a periphery of the first connection terminal and a periphery of the second connection terminal comprises:
forming a first dielectric material layer on a surface of the spacer where the bit line structure is formed, the first dielectric material layer filling up a gap between adjacent two of the first connection terminals;
forming a word line material layer on a surface of the first dielectric material layer, the word line material layer filling up a gap between adjacent two of the channel regions;
forming a second dielectric material layer on a surface of the word line material layer, the second dielectric material layer filling up a gap between adjacent two of the second connection terminals; and
etching the second dielectric material layer, the word line material layer and the first dielectric material layer to form, between adjacent rows of the plurality of active area structures, isolation trenches extending along the row direction of the plurality of active area structures to obtain the connection terminal dielectric layer and a plurality of word line structures extending along a column direction of the plurality of active area structures, each of the plurality of word line structures covering the channel regions of the plurality of active area structures positioned in the same column.

14. The method for fabricating a semiconductor structure according to claim 13, wherein after forming the isolation trenches, the method further comprises:
forming a filling dielectric layer in the isolation trenches, wherein the filling dielectric layer fills up the isolation trenches.

15. A memory structure, comprising:
the semiconductor structure according to claim 1;
a storage node structure positioned on a surface of the active area structure away from the substrate; and
a capacitor positioned on a surface of the storage node structure away from the active area structure.

16. The memory structure according to claim 15, wherein a plurality of active area structures, a plurality of storage node structures, and a plurality of capacitors are provided; the plurality of storage node structures are arranged in a one-to-one correspondence with the plurality of active area structures; and the plurality of capacitors are arranged in a one-to-one correspondence with the plurality of storage node structures.

17. A method for fabricating a memory structure, comprising:
fabricating the semiconductor structure by means of the method for fabricating a semiconductor structure according to claim 7;
forming a storage node structure on a surface of the active area structure away from the substrate; and
forming a capacitor on a surface of the storage node structure away from the active area structure.

18. The method for fabricating a memory structure according to claim 17, wherein a plurality of active area structures, a plurality of storage node structures, and a plurality of capacitors are provided; the plurality of storage node structures are arranged in a one-to-one correspondence with the plurality of active area structures; and the plurality of capacitors are arranged in a one-to-one correspondence with the plurality of storage node structures.
